(19) United States
(12) Patent Application Publication
(10) Pub. No.: US 2001/0045608 A1
(43) Pub. Date: Nov. 29, 2001

(54) TRANSISTER WITH A BUFFER LAYER AND RAISED SOURCE/DRAIN REGIONS

(76) Inventors: HUA-CHOU TSENG, HSIN-CHU CITY (TW); TONY LIN, HSIN-CHU CITY (TW)

Correspondence Address: LOWE HAUPTMAN GOPSTEIN, GILMAN & BERNER LLP, 1700 DIAGONAL ROAD SUITE 310, ALEXANDRIA, VA, 22314

(21) Appl. No.: 09/473,986

(22) Filed: Dec. 29, 1999

(51) Int. Cl. H01L 29/76

(52) U.S. Cl. 257/410

(57) ABSTRACT

A method for forming a high-speed device in an integrated circuit is disclosed. The approaches include reduction of gate-size and cutback on device capacitance and resistance. In the present invention, poly-trench etching followed by silicone selective growth and dielectric spacer formation are used to define gate length. A reduced gate size is therefore obtained. As with a dielectric buffer layer positioned below the source and drain regions, the proposed device possesses a largely decreased junction capacitance area. The design of air-gap spacer is to cut down on the overlap capacitance between gate and source/drain. Finally, with the application of raised polysilicon source and drain layers to behave as silicide consumption layer and the utilization of the buffer layer to provide diffusion protection, the silicide layer can be thickly formed to reduce sheet resistance without any increment on the junction leakage current.

### BACKGROUND OF THE INVENTION

1. Field of the Invention

The present invention relates to the fabrication of high performance semiconductor devices and, more particularly, to the fabrication of a MOSFET having a size-reduced gate structure with an air-gap spacer surrounded alongside and raised source/drain regions with dielectric buffer layers protected underneath.

2. Description of the Prior Art

The semiconductor industry is increasingly characterized by growing trend toward fabricating larger and more complex circuits on a given semiconductor chip. This is being achieved by reducing the size of individual devices within the circuits and spacing the devices closer together. The reduction of the size of individual devices and closer spacing brings about improved electrical performance. The size and geometry often relies on the photolithographic resolution available for the particular manufacturing facility. However, as line widths shrink smaller and smaller in submicron photolithography, the resolution of the image sizes becomes more difficult. The scaling-down of the devices is thus limited.

Besides scaling, one critical parameter to enhance electrical performance of the integrated circuits is the contact technology. Conventional contact structures, however, limit the device performance in several ways. One of the limitations is due to the fact that the area of the source/drain regions could not be minimized because the contact hole had to be aligned to these regions with a separate masking step, and extra area had to be allocated for misalignment. The extra area resulted in increased source/drain-to-substrate and source/drain-to-gate junction capacitance, which decreased the speed of the device.

A variety of contact structures have been proposed in an effort to solve the problems associated with shrinking the device. Two of the most important proposals are (1) self-aligned silicides (salicides) on the source/drain regions; and (2) a raised source/drain structure obtained by selectively depositing silicon onto the exposed source/drain regions.

The self-aligned silicide makes the diffused regions more conductive and lowers the sheet resistance of the diffused regions. The silicides that have been the most successful in semiconductor integrated circuit manufacturing have been titanium silicide and cobalt silicide. These two suicides exhibit the desired low resistivities and can withstand process temperatures in excess of 800° C. There is, however, a limitation with the process of silicide formation related to the fact that the gate and the source/drain silicides are typically formed at the same time. On the gate, it is desirable for the silicide to have the lowest possible sheet resistance so that the gate electrode will also have a low interconnect resistance. To achieve the low interconnect resistance, it is necessary for the gate to have a thick silicide layer. Over the source/drain regions, however, the silicide can only be of limited thickness, in order to prevent excess consumption of the substrate silicon by silicide formation. In addition, overly thick silicide layer within a conventional structure will induce junction leakage formation, and ultimately give rise to current leakage of the device.

The second proposed method for solving the problems associated with shrinking the MOSFET involves selective growth of silicone and diffusion of the implanted dopants to form the junctions. In this approach, the source/drain regions are formed in elevated sites to reduce the contact area towards gate region so as to minimize the source/drain-to-gate overlap capacitance. During the process, silicon is selectively grown over the source/drain regions, following the completion of oxide-spacer formation. For example, a process using SiH₂Cl₂—HCl gas under high temperature and reduced pressure is employed for the selective growth step to produce raised source/drain regions. In addition, a BF₂+is used to implant into the selectively grown film to form a low resistance shallow junction. Furthermore, a phosphorus implant into the selectively grown layer is performed to produce a gradual-drain n+junction so as to reduce hot-carrier degradation.

The up-mentioned conventional methods seem to overcome some of the problems, but there is still some redundant resistance and capacitance within a MOSFET can be further reduced. To cut down on these speed impediments, what is proposed here is a modified device structure with the application of raised source/drain structure and the utilization of salicide process. In addition, with the process of making this modified structure, the size of the gate length can be well reduced using the existing lithography techniques. Junction leakage prevention is also part of the design efforts. Shrinking gate size together with low capacitance/resistance product and improving junction leakage will surely improve the electrical performance of the device.

### SUMMARY OF THE INVENTION

The invention may be incorporated into a method for forming a semiconductor device structure, and the semiconductor device structure formed thereby. A source polysilicone layer and a drain polysilicone layer are formed simultaneously over a dielectric buffer layer overlying a substrate. An epitaxy channel extending from the substrate is grown between the source side and drain side. Then dielectric spacers are formed on the lateral of the source/ drain poly layers. Followed by the gate oxide formation on the channel layer, a gate electrode (polysilicone layer) is deposited upon the oxide. Planarization technique is then applied to facilitate the subsequent silicide formation. Prior to the silicide formation, the polysilicone layers of the gate and source/drain regions are implanted. Then a thick layer of silicide is form on the doped gate and source/drain regions by self-alignment. The dielectric spacers are now removed to form air gaps. An enhanced implantation is then performed to form LDD regions on the channel layer below the air gaps. Finally the device is under rapid thermal annealing to finish the construction of the structure.

In contrast with the conventional photolithography to pattern gate structure, poly-trench etching followed by silicone selective growth and dielectric spacer formation are used to define gate length in the present invention. A reduced gate size is therefore obtained. As with the existence of a dielectric buffer layer below the source and drain regions, the area of junction capacitance is largely decreased. The design of air-gap spacer is served to cut down on the overlap capacitance between gate and source/drain. In addition, with the application of raised polysilicon source and drain layers to behave as silicide consumption layer and the utilization of the buffer layer to provide diffusion protection, the silicide layer can be thickly formed to effectively reduce sheet resistance without any increment on the junction leakage current.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings. FIGS. 1-9 demonstrates procedure of fabricating the proposed device structure, wherein:

FIG. 1 shows the device with a dielectric buffer layer deposition according to the present invention.

FIG.2 shows the device with a poly source/drain layer deposition according to the present invention.

FIG.3 shows the device with poly trench definition of the source/drain poly layers and the dielectric buffer layers according to the present invention.

FIG.4 shows the device with epitaxial silicon grown in selected regions according to the present invention.

FIG.5 shows the device with spacer formation according to the present invention.

FIG.6 shows the device with a gate oxide layer formation and a poly gate layer deposition according to the present invention.

FIG.7 shows the device structure after planarization process according to the present invention.

FIG. 8 shows the device with salicide layer formation according to the present invention.

FIG.9 shows the device with the spacer removal and a complete structure according to the present invention.

### DESCRIPTION OF THE PREFERRED EMBODIMENT

The process steps and structures described below do not form a complete process flow for manufacturing integrated circuits. The present invention can be practiced in conjunction with integrated circuit fabrication techniques currently used in the art, and only so much of the commonly practiced process steps are included as are necessary for an understanding of the present invention. The figures representing cross-sections of portions of an integrated circuit during fabrication are not drawn to scale, but instead are drawn so as to illustrate the important features of the invention.

Referring now to FIGS. 1-9, a preferred embodiment of the present invention is described in details. As shown in FIG. 1, an integrated circuit is to be formed on a silicon substrate 10. The silicon substrate may be p- or n- doped silicon depending upon the location in the wafer where the isolation and active devices are to be formed. Trench isolation regions 12 are formed on various portions of the wafer to isolate the active areas where devices will be formed. A dielectric layer 14 such as oxide or nitride is formed over the substrate 10 and the isolation regions 12 to a depth of between approximately 500 to 800 angstroms.

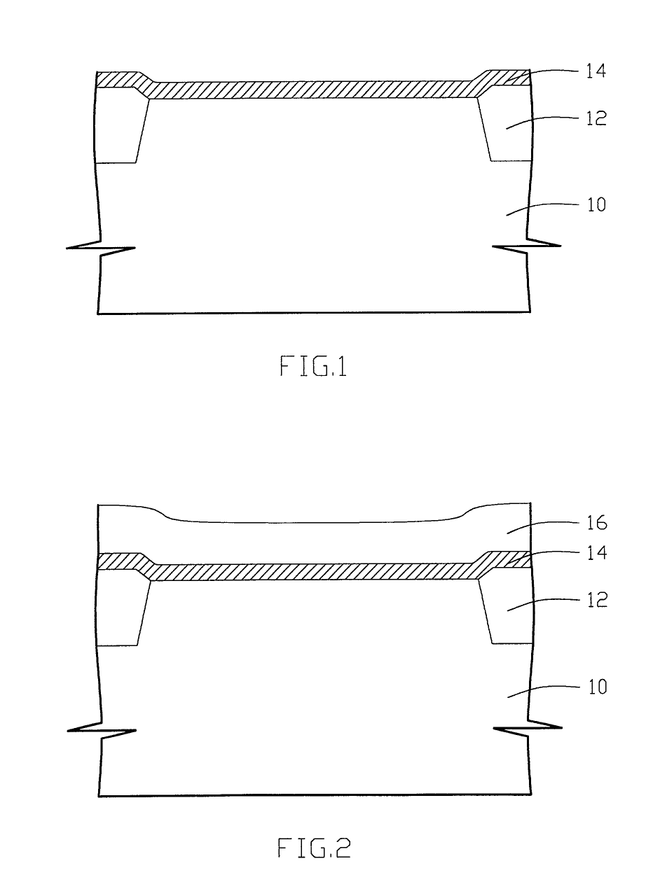

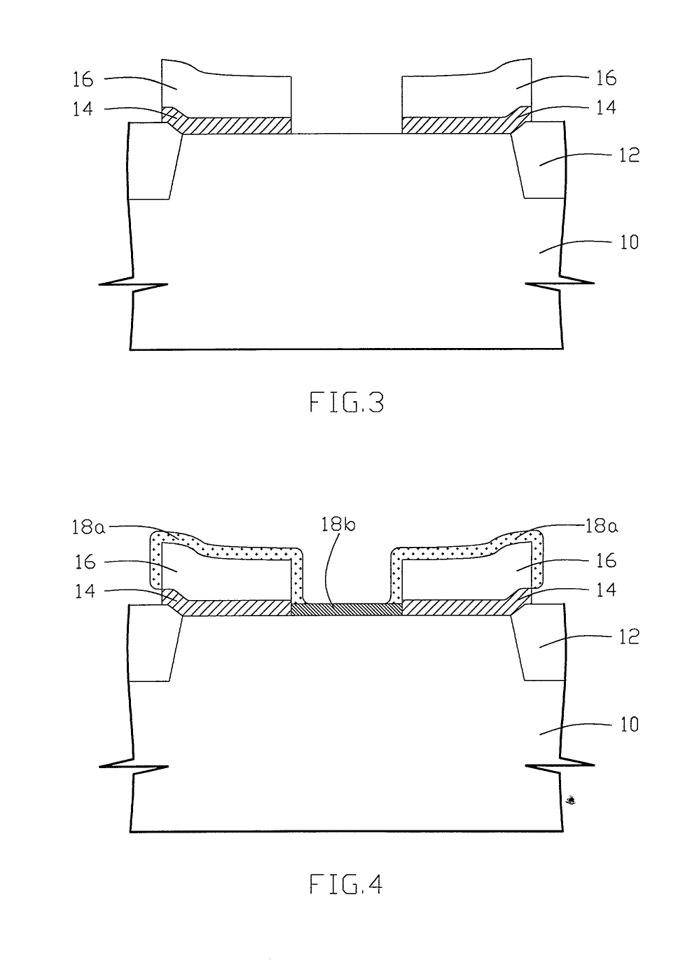

Next, a layer of polysilicon 16 of between 1500 to 3500 angstroms is deposited over the dielectric layer 14, as indicated in FIG.2. The polysilicon layer 16 and dielectric layer 14 are then trench defined and etched to form elevated regions, as illustrated in FIG.3. Note that the smallest mask size used for trench definition herein would be the photolithography limitation which typically patterning the smallest gate structure in conventional process. The space between the elevated regions, which used to hold only the main body of a gate structure, is now to be filled also with other indispensable layers for the device to operate. This obviously results in an even smaller gate length than any current photolithographic image can attain by conventional patterning.

After the formation of the polysilicone layers for source and drain regions, a channel layer is now to be created by selective epitaxial growth (SEG) of silicon. Referring to FIG.4, A layer of silicon is deposited over the device surface. Since epitaxial growth of silicon would not occur on the surrounding regions such as oxide, and the deposition over the source/drain poly layers shall extend the polysilicon formation, the growth of the epitaxial silicon will only be above the silicon substrate 10. Thus layer 18b turns to be a Si-SEG channel while 18a represents a new layer of polysilicon and eventually becomes extenders of the source and drain poly layers.

A dielectric layer is then deposited over the device surface to a depth of between approximately 1000 to 2000 angstroms. Following the deposition, etch back the dielectric layer to form spacers 20 as shown in FIG.5. The gate length is herein established.

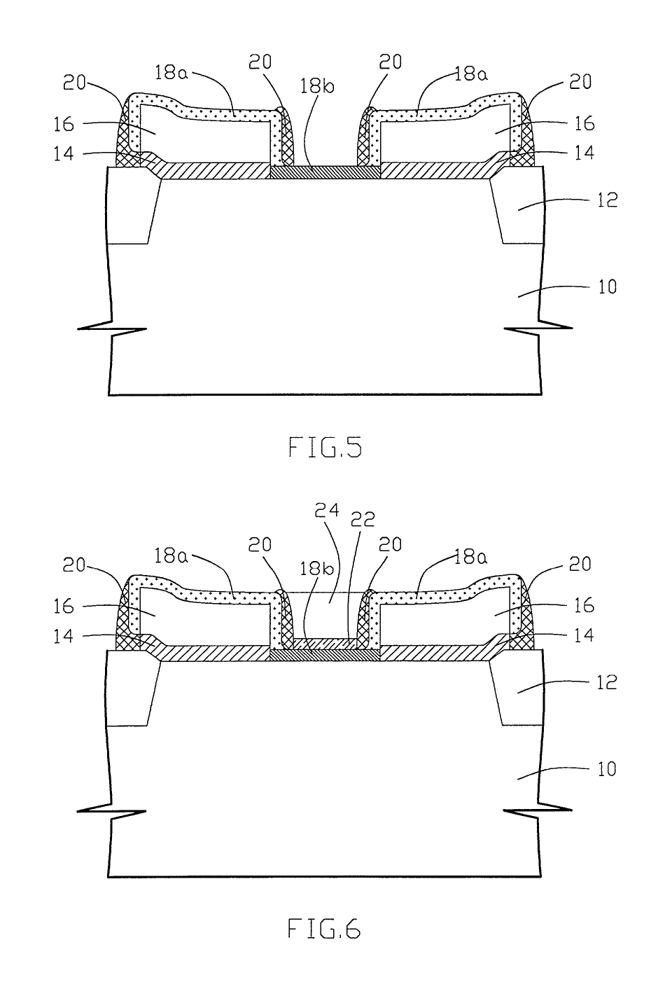

The gate oxide layer 22 is now thermally grown over the channel layer 18b as illustrated in FIG.6. A layer of polysilicon 24 is deposited next over the gate oxide 22 to a depth between approximately 2000 to 5000 angstroms.

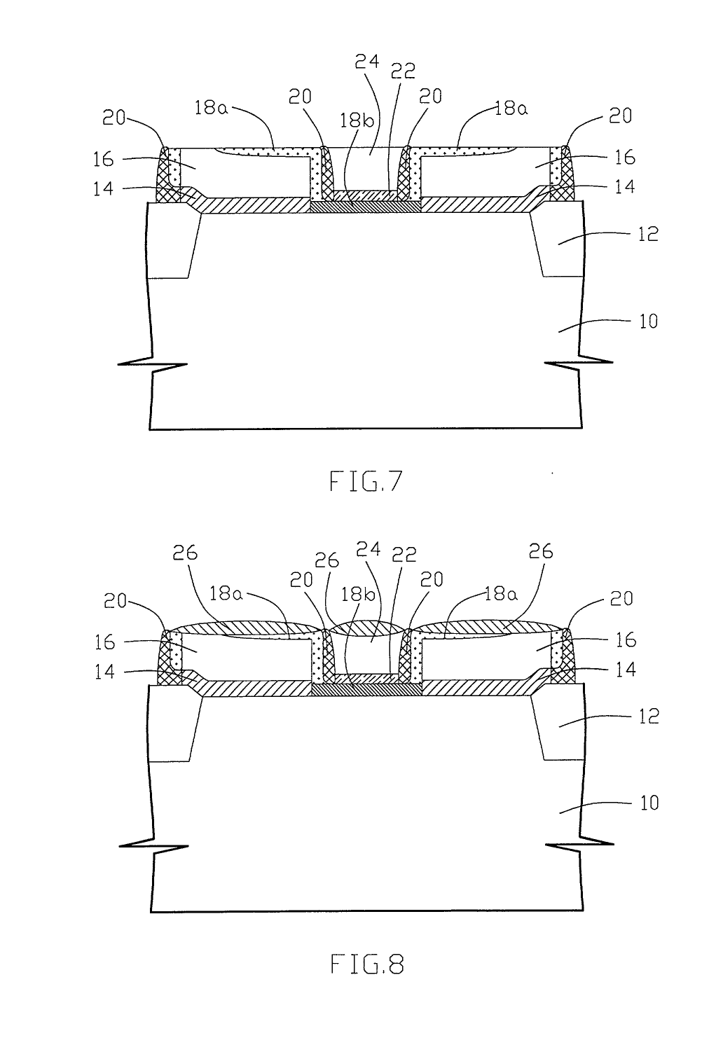

Then, additional planarizing process is applied to reduce height non-uniformities at the device surface by techniques such as etching back or chemical-mechanical polishing. A planar device surface is thus obtained, as shown in FIG.7 to facilitate subsequent layer deposition. After the planarization, gate interconnects are then defined to distinct each device before the succeeding implantation process proceeds.

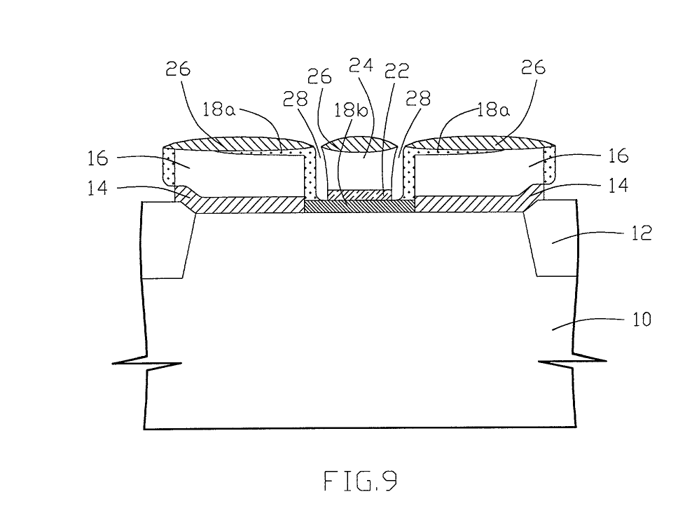

The implantation is performed prior to the silicide formation. The gate layer 24 and the source/drain poly layers 16, 18a are implanted with N+or P+dopant. A metal layer, such as a refractory metal (such as Ti or Co) layer, is then deposited on top of the device surface. Silicide layer 26 is thus selectively formed over exposed polysilicon regions, as shown in FIG.8. If the silicide layer and polysilicon layers were self-aligned to each other, the silicide layer 26 could be termed salicide layer 26. When defining the thickness of the silicide layer 26, a thick layer of silicide on the gate electrode is preferred for the purpose of resistance reduction. Besides, in the present invention, with the additional dielectric layer 14 buffered underneath as a diffusion barrier, there is no more concerns about the metallurgical junction approach of the silicide boundary in the source/drain regions that may induce leakage current. As for the dielectric buffer layer 14, its existence can largely cut down the area of junction capacitance used to hold within a conventional structure.

Following the silicide formation, the dielectric spacers 20 are etched away to form air gaps, as illustrated in FIG.9, to later facilitate doping on the channel layer. The air gaps separate the gate electrode from the source and drain and serve as well as solid spacers. In addition, without substantial contact media, the air-gap spacers have the advantage of reducing the overlap capacitance between gate and source/drain. Lightly doped drain (LDD) implantation is then performed on the channel 18b in the regions below the air-gap spacer. This additional implantation step is to enhance the channel conductivity towards the source and drain regions. Finally, apply rapid thermal anneal (RTA) to activate the dopants and improve the device integrity, and the construction of the device structure is then concluded.

In contrast with the conventional photolithography of patterning a gate structure, poly-trench etching followed by silicone selective growth and dielectric spacer formation are used to define gate length in the present invention. A reduced gate size is therefore obtained. As with the dielectric buffer layer below the source and drain regions, the proposed device possesses a largely decreased junction capacitance area. The design of the air-gap spacer is served here to cut down on the overlap capacitance between gate and source/drain. In addition, with the application of the raised polysilicon source and drain layers to behave as silicide consumption layer and the utilization of the buffer layer to provide diffusion protection, the silicide layer can be thickly formed to reduce sheet resistance without any increment on the junction leakage current. Although specific embodiments have been illustrated and described, it will be obvious to those skilled in the art that various modifications may be made without departing from what is intended to be limited solely by the appended claims.

What is claimed is:

1. A device structure within an integrated circuit, comprising:
a source region and a drain region, both positioned above a substrate;
a first buffer layer and a second buffer layer, wherein said first buffer layer interposed between said source region and said substrate and said second buffer layer interposed between said drain region and said substrate;
a channel region located on said substrate separating said first buffer layer/the bottom part of said source region from said second buffer layer/the bottom part of said drain region;
a gate region formed on top of said channel region; wherein a plurality of air-gap regions separating said gate region from said source region and said drain region.

2. The structure of claim 1, wherein said source region and said drain region both comprise a polysilicon layer and a first silicide layer.

3. The structure of claim 2, wherein said first silicide layer comprises a salicide layer.

4. The structure of claim 1, wherein said gate region comprises a gate oxide layer, a polysilicon layer and a second silicide layer.

5. The structure of claim 4, wherein said second silicide layer comprises a salicide layer.

6. The structure of claim 1, wherein the formation of said source and drain regions comprises trench etching.

7. The structure of claim 1, wherein said source and drain regions are doped.

8. The structure of claim 7, wherein said gate region is doped with a concentration approximately the same with that of said source and drain regions.

9. The structure of claim 7, wherein said channel region is doped at areas below said air gaps with a concentration lower than that of said source and drain regions.

10. The structure of claim 1, wherein said first buffer layer and said second buffer layer each comprises a dielectric layer.

11. The structure of claim 10, wherein said dielectric layer is selected from the group consisting of oxide and nitride.

12. The structure of claim 1, wherein the thickness of said first buffer layer and said second buffer layer is between 500 to 800 angstroms.

13. The structure of claim 1, wherein said channel region comprises epitaxy silicon.

14. A device structure within an integrated circuit, comprising:
a doped source region and a doped drain region, both positioned above a substrate and each comprising a polysilicon layer and a first silicide layer;
a first buffer layer and a second buffer layer, wherein said first buffer layer interposed between said source region and said substrate and said second buffer layer interposed between said drain region and said substrate;
a channel layer located on said substrate separating said first buffer layer/the bottom part of said source region from said second buffer layer/the bottom part of said drain region, wherein said channel layer is doped at the regions adjacent to said first buffer layer/said second buffer layer and said source/drain regions with a concentration lower than that of said source and drain regions;
a gate region formed on top of said channel layer comprising a gate oxide layer, a polysilicon layer and a second silicide layer; wherein a plurality of air-gap regions separating said gate region from said source region and said drain region.

15. The structure of claim 14, wherein said first buffer layer and said second buffer layer each comprises a dielectric layer.

16. The structure of claim 15, wherein said dielectric layer is selected from the group consisting of oxide and nitride.

17. The structure of claim 14, wherein the thickness of said first buffer layer and said second buffer layer is both between 500 to 800 angstroms.

18. The structure of claim 14, wherein said channel layer comprises epitaxy silicon.

19. The structure of claim 14, wherein said first silicide layer and second silicide layer both comprise a salicide layer.

20. The structure of claim 14, wherein the formation of said source and drain regions comprises trench etching.
